(19) United States
(12) Patent Application Publication
(10) Pub. No.: US 2006/0160359 A1
(43) Pub. Date: Jul. 20, 2006

(54) Vacuum processing apparatus

(75) Inventors: Shigeru Kasai, Yamanashi (JP); Susumu Katoh, Yamanashi (JP); Tomohito Komatsu, Yamanashi (JP); Tetsuya Saito, Yamanashi (JP); Sumi Tanaka, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/546,803

(22) PCT Filed: Feb. 12, 2004
(86) PCT No.: PCT/JP04/01479

§ 371 Date: Aug. 25, 2005

(30) Foreign Application Priority Data
Feb. 26, 2003 (JP) 2003-49632

(51) Int. Cl. H01L 21/44; C23C 16/00

(52) U.S. Cl. 438/680; 118/715

(57) ABSTRACT

A vacuum processing apparatus is constituted of the following portions: a processing container with the bottom, capable of drawing vacuum; a placement platform installed in the container; a heating portion for heating a substrate on the platform; a processing gas-feeding portion for feeding a processing gas into the container; a partitioning portion surrounding a space between the platform and the bottom of the container and partitioning off the space from a processing space in the container; a purge gas-feeding portion for feeding a purge gas into the space surrounded by the partitioning portion; a purge gas-discharging portion for discharging the purge gas from the space surrounded by the partitioning portion; a control portion for controlling the purge gas-feeding portion and/or the purge gas-discharging portion so as to regulate the pressure in the space surrounded by the partitioning portion; and a temperature-detecting portion penetrating the bottom of the container, inserted in the space surrounded by the partitioning portion, and having the top end in contact with the platform. The partitioning portion has the lower end in surface-contact with the bottom of the container. The control portion regulates the pressure in the space surrounded by the partitioning portion to a pressure higher than that in the processing space in the container.

### FIELD OF THE INVENTION

The present invention relates to a vacuum processing apparatus for carrying out e.g., a film forming process on a substrate in a vacuum atmosphere (depressurized state).

### BACKGROUND OF THE INVENTION

The manufacturing process of a semiconductor device includes a process of forming wiring by burying a metal or metal compound in holes or grooves formed in a semiconductor wafer (hereinafter, referred to as ‘wafer’) by CVD (chemical vapor deposition). An apparatus for forming a film of a metal or metal compound on a wafer is disclosed, for example, in Japanese Patent Laid-open Application No. 2003-133242 (Japanese Patent Application No. 2001-384649).

The film forming apparatus described in Japanese Patent Laid-open Application No. 2003-133242 is schematically shown in FIG. 7. Reference numeral 1 is a chamber whose upper portion is a flat cylindrical part 1a while the chamber's lower portion is a cylindrical part 1b with a smaller diameter. Installed in the cylindrical part 1a is a mounting table 12 made of ceramic material in which heaters 11a and 11b made of a resistance heating element are embedded. The upper portion of a cylindrical member 13 made of ceramic material is in contact with the central portion in the rear surface of the mounting table 12. An opening part 14 is formed in the central portion in the bottom surface of the chamber 1. The lower end of the cylindrical member 13 is placed over the bottom surface of the chamber 1 with a ring-shaped resin sealing member (O-Ring) 15 therebetween in an airtight manner to surround the opening part 14. Therefore, the interior of the cylindrical member 13 is in atmospheric condition. Disposed in the cylindrical member 13 are power supply cables 16a and 16b for supplying electric power to the respective heaters 11a and 11b and a thermocouple 17 for detecting the temperature of the mounting table 12.

The heater 11a is installed in the central portion of the mounting table 12. The heater 11b is disposed in a ring-shape around the periphery of the heater 11a. The top end of thermocouple 17 is in contact with the central portion of the mounting table 12 to detect temperature of the contact area. Based on the temperature, the electric power levels to the heaters 11a and 11b are controlled e.g., while maintaining the ratio of the power levels at a certain value.

Above the mounting table 12, a gas supply unit 18 referred to as “gas shower head” is installed to supply gas over the entire surface of a wafer 10 with high uniformity. While a processing gas is supplied from the gas supply unit 18, pumping is performed through an exhaust port (not shown) provided at the bottom of the cylindrical part 1b, so that the interior of the chamber 1 is maintained at a certain vacuum level. The processing gas reacts thermochemically on the surface of the wafer 10, thereby forming on the surface of the wafer 10 a thin film of, e.g., a metal or metal compound of W (tungsten), WSix (tungsten silicide), Ti, TiN (titanium nitride) or the like.

The cylindrical member 13 isolates the space occupied by the power supply cables 16a and 16b and the thermocouple 17 from the processing gas atmosphere to thereby prevent their corrosion by a film forming gas or a cleaning gas during cleaning. Further, the cylindrical member 13 aids the thermocouple 17 to detect the temperature with high accuracy. The thermocouple 17 detects the temperature of the mounting table 12 by a contact between the tip of the thermocouple 17 and the mounting table 12. If the corresponding contact regions are exposed to the processing gas atmosphere, the heat conductance of the gap between the contact regions would vary because the pressure of the gas atmosphere would fluctuate depending on whether the processing gas flows or not. As a result, controlling temperature becomes unstable. To avoid this problem, the interior of the cylindrical member 13 is hermetically isolated from the processing gas atmosphere. In this example, the interior of the cylindrical member 13 is at atmospheric pressure.

Meanwhile, as the size of the wafer 10 becomes increasingly bigger, one of the issues is how to perform processing with high uniformity over the entire surface. Therefore, the temperature of the mounting table 12 needs to be controlled with superior accuracy. However, in the above apparatus, the temperature of the mounting table 12 is detected only at the central portion thereof. Therefore, when the mounting table 12's peripheral portion temperature is disturbed by external factors, for example, it is unable to control the temperature after its disturbance.

Further, in order to have a thermocouple 17 in the area where the outer heater 11b is disposed, the diameter of the cylindrical member 13 needs to be bigger. If so, the volume of the chamber 1 will become bigger considerably and the overall apparatus will become bulkier.

Moreover, as shown in FIG. 7, even if the cylindrical member 13 having a small diameter is used, which is connected to the central portion of the mounting table 12, this arrangement will offer little benefit to the overall installation space because the length of the lower portion of the cylindrical part 1b needs to be long. (If the temperature of the mounting table 12 is within the range from, e.g., 500° C. to 700° C., this heat will be transmitted to the bottom of the chamber 1 via the cylindrical member 13. Since the O-Ring 15, placed between the bottom of the chamber 1 and the lower end of the cylindrical member 13, has a low heat resistance, the length of the cylindrical member 13 needs to be considerably long.)

Furthermore, as a film forming process is carried out repeatedly, the thickness of the thin film deposited on the mounting table 12 becomes increasingly thicker. Therefore, there is a concern for particles coming off the film and thus the inside of the chamber 1 is cleaned regularly with cleaning gas. However, this introduces a problem in that it takes a long time to start cleaning after finishing the film forming process. To elaborate, as for the temperature of the mounting table 12 during cleaning, it is at e.g., 250° C. which is lower than during the film forming process, but it will take a long time to dissipate the heat of the mounting table 12 and lower its temperature because the periphery of the mounting table 12 is in a vacuum atmosphere. Otherwise, if the inner pressure of the chamber 1 is raised to speed up the heat transfer rate, it will take a long time to form a vacuum in the film forming apparatus to reach a suitable pressure level for performing cleaning.

### SUMMARY OF THE INVENTION

The present invention has been made to address the prior art problems discussed above. It is an object of the present invention to provide a vacuum processing apparatus, wherein a temperature detecting unit which detects temperature of a mounting table is protected from corrosion by preventing processing gas from getting into the rear surface side of the mounting table; and in case a power line member is provided for supplying electric power to a resistance heating element, the power line member is also protected from corrosion. The vacuum processing apparatus also allows the distance between the mounting table and the bottom of the processing vessel to be shorter by not having the problem of thermal degradation of a resin sealing member. It is another object of the present invention to provide a vacuum processing apparatus capable of rapidly decreasing the temperature of the mounting table for superior operational efficiency.

In accordance with the one aspect of the present invention, there is provided a vacuum processing apparatus comprising: a processing vessel with a bottom, the vessel drawing a vacuum; a mounting table installed in the processing vessel for mounting a substrate thereon; a heating unit for heating the substrate on the mounting table; a processing gas supply unit for supplying a processing gas into the processing vessel; an enclosing unit surrounding a space between the mounting table and the bottom of the processing vessel so that the space is isolated from a processing space of the processing vessel; a purge gas supply unit for supplying a purge gas into the space surrounded by the enclosing unit; a purge gas exhaust unit for exhausting the purge gas from the space surrounded by the enclosing unit; a control unit for controlling the purge gas supply unit and/or the purge gas exhaust unit to regulate the pressure in the space surrounded by the enclosing unit; and a temperature detecting unit which penetrates the bottom of the processing vessel and runs through the space surrounded by the enclosing unit with a top end of the temperature detecting unit contacting the mounting table, wherein the enclosing unit has a lower end in surface contact with the bottom of the processing vessel and the control unit regulates the pressure in the space surrounded by the enclosing unit to be higher than that in the processing space of the processing vessel.

In accordance with the present invention, the space below the mounting table is enclosed by the enclosing unit so that the pressure in the enclosing unit stays at a positive pressure without recourse to a resin sealing member. Therefore, gas is prevented from leaking into the enclosed region; and thus a temperature detection unit is protected from corrosion by processing or cleaning gas. Further, since the resin sealing member is not used between the enclosing unit and the bottom of the processing vessel, there is no potential problem about thermal degradation of the resin sealing member by heat transmitted from the mounting table. Therefore, the distance between the mounting table and the bottom of the processing vessel can be reduced.

It is preferable that the heating unit has a resistance heating element disposed in the mounting table, and a power line member for supplying electric power to the heating unit penetrates the bottom of the processing vessel and runs through the space surrounded by the enclosing unit. In this case, the power line member is protected from corrosion by processing or cleaning gas.

Preferably, the control unit raises the pressure in the space surrounded by the enclosing unit.

Further, it is preferable that the vacuum processing apparatus further comprises a purge gas cooler unit for cooling the purge gas. In this case, the control unit also controls the purge gas cooler unit.

It is preferable that the processing vessel has a sidewall portion while a buffer plate is provided between the sidewall portion and the enclosing unit to divide the processing space of the processing vessel into a processing space side and an exhausting space side and the buffer plate has a plurality of holes for permitting the processing space side to communicate with the exhausting space side, and a processing gas exhaust port is provided in the sidewall portion for exhausting the processing gas from the exhausting space side.

In this embodiment, the buffer plate has a temperature control unit.

In accordance with another aspect of the present invention, there is provided a vacuum processing method using a vacuum processing apparatus comprising a processing vessel with a bottom, the vessel drawing a vacuum; a mounting table installed in the processing vessel for mounting a substrate thereon; a heating unit for heating the substrate on the mounting table; a processing gas supply unit for supplying a processing gas into the processing vessel; an enclosing unit surrounding a space between the mounting table and the bottom of the processing vessel so that the space is isolated from a processing space of the processing vessel; a purge gas supply unit for supplying a purge gas into the space surrounded by the enclosing unit; a purge gas cooler unit for cooling the purge gas; a purge gas exhaust unit for exhausting the purge gas from the space surrounded by the enclosing unit; a control unit for controlling the purge gas supply unit and/or the purge gas exhaust unit to regulate the pressure in the space surrounded by the enclosing unit; and a temperature detecting unit which penetrates the bottom of the processing vessel and runs through the space surrounded by the enclosing unit, with a top end of the temperature detecting unit contacting the mounting table, wherein the enclosing unit has a lower end in surface contact with the bottom of the processing vessel, the vacuum processing method comprising: a processing process for vacuum processing of the substrate while regulating the pressure in the space surrounded by the enclosing unit to be higher than that in the processing space of the processing vessel; and a cooling process for reducing the temperature of the mounting table while maintaining a raised pressure level in the space surrounded by the enclosing unit, both being carried out after the vacuum processing.

In accordance with still another aspect of the present invention, the vacuum processing method further comprises a cleaning process for cleaning the inside of the processing vessel after the cooling process.

In accordance with still another aspect of the present invention, there is provided a vacuum processing method using a vacuum processing apparatus comprising a processing vessel with a bottom, the vessel being drawing a vacuum; a mounting table installed in the processing vessel for mounting a substrate thereon; a heating unit for heating the substrate on the mounting table; a processing gas supply unit for supplying a processing gas into the processing vessel; an enclosing unit surrounding a space between the mounting table and the bottom of the processing vessel so that the space is isolated from a processing space of the processing vessel; a purge gas supply unit for supplying a purge gas into the space surrounded by the enclosing unit; a purge gas exhaust unit for exhausting the purge gas from the space surrounded by the enclosing unit; a control unit for controlling the purge gas supply unit and/or the purge gas exhaust unit to regulate the pressure in the space surrounded by the enclosing unit; and a temperature detecting unit which penetrates the bottom of the processing vessel and runs through the space surrounded by the enclosing unit, with a top end of the temperature detecting unit contacting the mounting table, wherein the enclosing unit has a lower end in surface contact with the bottom of the processing vessel, the vacuum processing method comprising: a processing process for vacuum processing of the substrate while regulating the pressure in the space surrounded by the enclosing unit to be higher than that in the processing space of the processing vessel; and a cooling process for reducing the temperature of the mounting table while cooling the purge gas by the purge gas cooler unit, both being carried out after the vacuum processing.

### BRIEF DESCRIPTION OF THE DRAWINGS

FIG. 1 shows a longitudinal cross sectional view of the entire configuration of a vacuum processing apparatus (film forming apparatus) in accordance with a preferred embodiment of the present invention.

FIG. 2 shows a schematic diagram of a control system of the vacuum processing apparatus of FIG. 1.

FIG. 3 shows gas flows in the surface contact regions of the enclosing unit which encloses the space below the mounting table.

FIG. 4 is a flow chart to illustrate the processing of the vacuum processing apparatus of FIG. 1.

FIG. 5 shows a longitudinal cross sectional view of a part of the vacuum processing apparatus (film forming apparatus) in accordance with another preferred embodiment of the present invention.

FIG. 6 provides a simplified diagram for showing an example of a purge gas cooler unit.

FIG. 7 describes a longitudinal cross sectional view of a schematic configuration of a conventional vacuum processing apparatus.

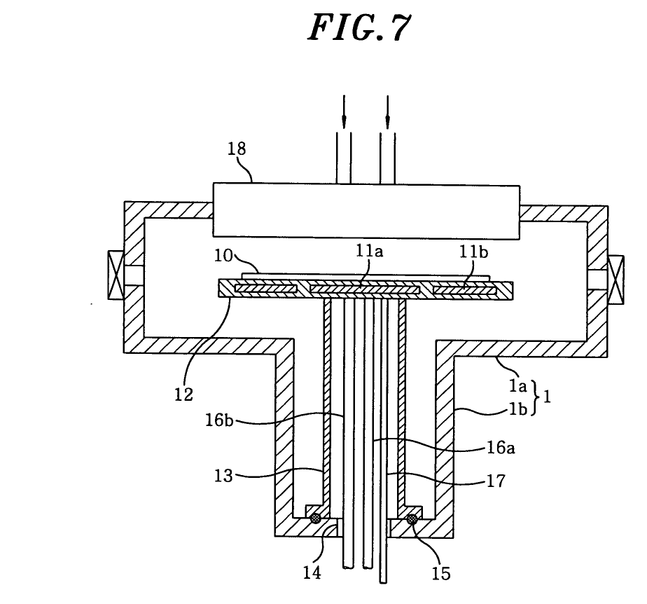

### DETAILED DESCRIPTION OF THE PREFERRED EMBODIMENT

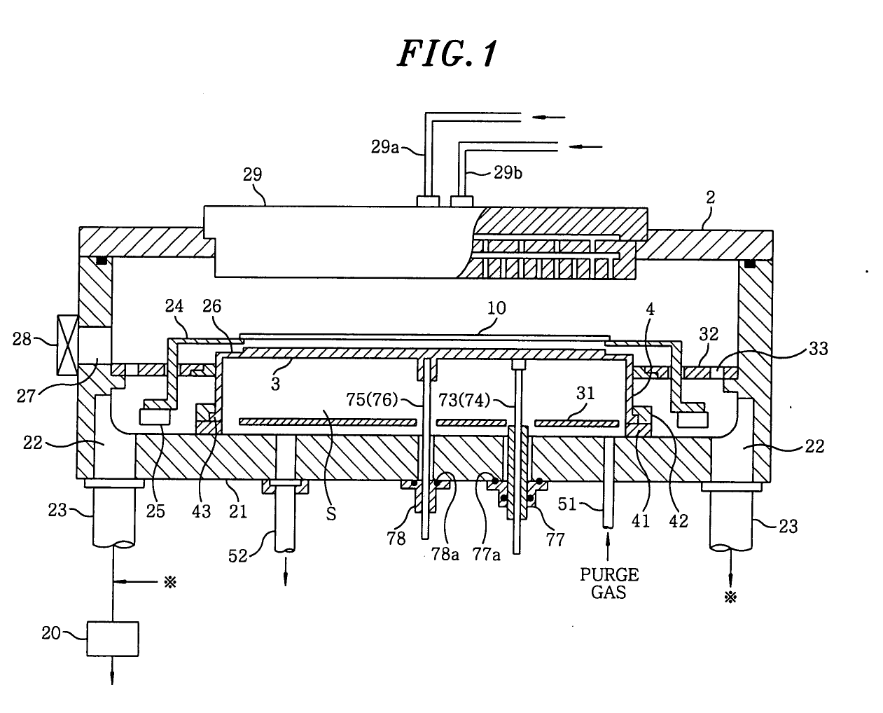

FIG. 1 shows the entire configuration of a vacuum processing apparatus in accordance with a preferred embodiment of the present invention. The vacuum processing apparatus of the preferable embodiment is, for example, a film forming apparatus for forming a Ti or a TiN film, and has an airtightly sealed cylindrical processing vessel (vacuum chamber) 2. In the processing vessel 2, a mounting table 3 as a substrate supporting unit, is disposed to horizontally support a substrate, e.g., wafer 10. The mounting table 3 is in a circle shape whose size is bigger than wafer 10. A cylindrical part 4 connected to the periphery of the mounting table 3 vertically extends down from its underside. The mounting table 3 and the cylindrical part 4 made of, e.g., a ceramic material such as aluminum nitride (AlN) or alumina (Al₂O₃), as one unit, make up a cylindrical member, which has an open top portion and a lower end with a bottom.

Further, a ring-shaped heat insulating material 41, whose size is about the diameter of the cylindrical part 4, is placed on the inner wall surface of the bottom wall 21 of the processing vessel 2. The heat insulating material 41 is formed of, for example, quartz. The heat insulating material 41 whose cross sectional shape is rectangular, is in surface contact with the inner wall surface of the bottom wall 21. A ring-shaped pressing member 42 whose cross sectional shape is of an inverted “L”, is mounted on the heat insulating material 41. The pressing member 42 is in surface contact with the top surface of the heat insulating material 41. The lower end of the cylindrical part 4 radially protrudes out, thereby, forming a flange (collar) 43. The flange 43 is fitted into an inwardly opened ring-shaped groove formed by the heat insulating material 41 and the pressing member 42. The cylindrical part 4, the heat insulating material 41 and the pressing member 42 are in surface contact with one another. Respective contact surfaces of the inner wall surface of the bottom wall 21, the heat insulating material 41, the pressing member 42 and the cylindrical part 4, are polished. Accordingly, by making surface contact with each other, a tight sealing is achieved as much as possible.

As a result, the space S between the mounting table 3 and the bottom of the processing vessel 2 becomes enclosed by the cylindrical part 4, the heat insulating material 41 and the pressing member 42, so that the space S is isolated from the processing atmosphere. Hence, in this embodiment, the cylindrical part 4, the heat insulating material 41 and the pressing member 42 correspond to an enclosing unit.

Further, connected to the bottom wall 21 of the processing vessel 2 are a purge gas supply line 51 forming a purge gas supply unit for supplying an inert gas such as nitrogen gas into the space S, and a purge gas exhausting line 52 forming a purge gas exhaust unit pumping the purge gas from the space S.

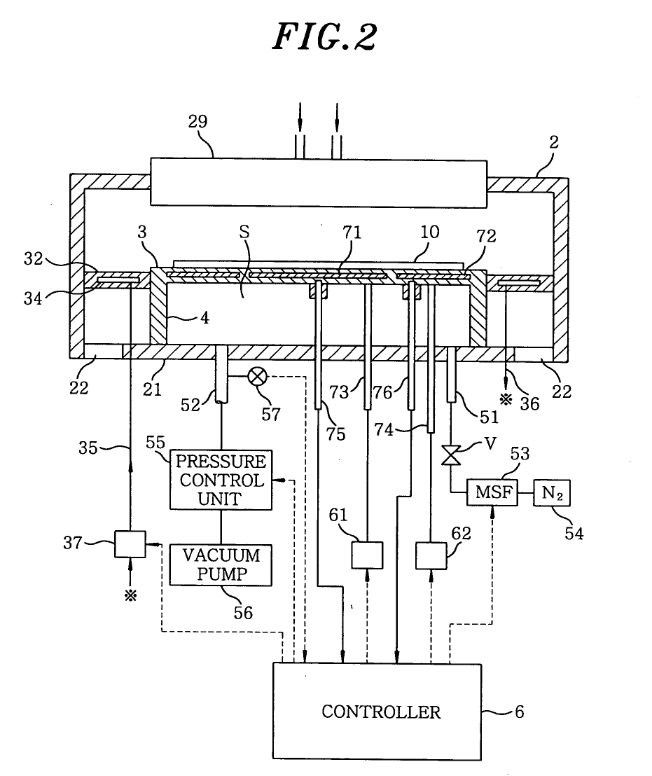

FIG. 2 shows a schematic view of a power supply system and a control system of the film forming apparatus in FIG. 1. As shown in FIG. 2, a purge gas supply source 54 is connected to the purge gas supply line 51 through a valve V and a mass flow controller 53 which is a flow rate control unit. A vacuum pump 56 as a vacuum exhaust unit is connected to the purge gas exhausting line 52 via a pressure control unit 55, such as a butterfly valve (constituting a control unit of Claim 1 with a controller 6 to be described below). Further, as for the vacuum pump 56, for example, a vacuum pump 20 for exhausting the inside of the processing vessel 2 described below can be used. A pressure detection unit 57 for detecting the pressure of the space S is disposed in the vicinity of the purge gas exhausting line 52 of the processing vessel 2.

In FIG. 2, reference numeral 6 indicates the controller (constituting the control unit of Claim 1 with the pressure control unit 55 discussed above). Based on the pressure value detected by the pressure detection unit 57, the controller 6 functions to control the pressure of the space S by transmitting a control signal to the pressure control unit 55 and to control the flow rate of the purge gas by transmitting a control signal to the mass flow control unit 53. Further, the pressure in the space S is regulated to be higher than the pressure of the processing atmosphere by the pressure control of the controller 6. Further, when reducing the temperature of the mounting table 3 (for example, when shifting to the cleaning process of the inside of the processing vessel 2 after terminating the film forming process of the wafer 10 by the processing gas), the pressure in the space S is controlled to be raised to efficiently transfer heat of the mounting table 3 to the bottom wall 21 of the processing vessel 2 via the purge gas. In other cases except when reducing the temperature of the mounting table 3 (for example, from the preparation stage of the film forming process to the termination of the continuous film forming of the wafer 10), the pressure in the space S is set within a range from, e.g., 133 Pa to 2660 Pa, which would allow detection of highly accurate temperature values via an adequate heat transfer through the minute gap between the top end of a thermocouple described below and the corresponding contact region of the mounting table 3.

In the mounting table 3, as shown in FIG. 2, a heating unit which is a heater 7 made of, e.g., a resistance heating element is installed. In this embodiment, the heater 7 has a circular or a ring-shaped heater 71 disposed in the central portion of the mounting table 3 and a ring-shaped heater 72 disposed in the periphery of the heater 71. In the space S, for example, power line members 73 and 74 such as power supply cables are inserted from the outside through the bottom of the processing vessel 2. The top ends of the power line members 73 and 74 are electrically connected to the heaters 71 and 72, respectively. Accordingly, electric power is individually supplied from power supply units 61 and 62 located at the other top ends of the power line members 73 and 74 to the heaters 71 and 72, respectively. Further, in the space S, the temperature detecting units such as the thermocouples 75 and 76 are inserted from the outside through the bottom of the processing vessel 2. The top ends of the thermocouples 75 and 76 are contacted to the lower portion side of the heating region of the heaters 71 and 72, respectively, in the mounting table 3 (for example, inserted into the holes protruding from the bottom surface side of the mounting table 3). Based on a temperature value detected by the thermocouple 75, the controller 6 controls the heat discharge rate of the inner heater 71 by sending a control signal to the power supply unit 61. Based on a temperature value detected by the thermocouple 76, the controller 6 also controls the heat discharge rate of the outer heater 72 by sending a control signal to the power supply unit 62.

Further, in FIG. 1, descriptions of the heaters 71 and 72 are omitted for simplicity, and only one of the power line members 73 and 74 and one of the thermocouples 75 and 76 are shown. As shown in FIG. 1, the power line members 73 and 74 are secured to the corresponding bottom wall 21 by installation members 77 with integrated sleeves and ring-shaped resin sealing members, O-Rings 77a while ensuring a tight sealing with the bottom wall 21 of the processing vessel 2. Moreover, the thermocouples 75 and 76 are secured to the corresponding bottom wall 21 by installation members 78 with integrated sleeves and O-Rings 78a ensuring a tight sealing with the bottom wall 21 of the processing vessel 2. In this embodiment, the heater is divided into 2 parts, however it can be divided into 3 or more parts. Each heater can be controlled individually by each power line member and thermocouple, both of which are provided per the number of the divided parts.

Further, between the mounting table 3 and the bottom wall 21 of the processing vessel 2, a reflecting plate 31 of which top surface is a reflective surface such as mirror surface is disposed to face the mounting table 3 to reflect radiant heat from the mounting table 3 back to the mounting table 3. With the reflecting plate 31, not only is it possible to curb temperature rise of the bottom wall 21, the heating efficiencies of the heaters 71 and 72 are also enhanced. Otherwise, the reflective surface can be formed by coating the surface of the bottom wall of the processing vessel with the mirror surface.

In the peripheral portion of the bottom wall 21 in the processing vessel 2, for example, a plurality of exhaust ports 22 are formed towards the circumference thereof. The vacuum pumps 20, as vacuum exhaust units, are connected to the exhaust ports 22 via exhaust lines 23. Accordingly, the inside of the processing vessel 2 is exhausted to a vacuum. In the periphery of the cylindrical part 4, a buffer plate 32 which extends in a circumferential direction, is disposed to block off a space between the cylindrical part 4 and the sidewall of the processing vessel 2. In the buffer plate 32, a plurality of holes are formed in a circumferential direction so that the processing gas from the processing space can be exhausted uniformly to the exhaust port 22 along the circumferential direction of the wafer 10. Thus, although the surface contact regions of the cylindrical part 4, the heat insulating material 41, the pressing member 42 and the bottom wall 21 of the processing vessel 2, e.g., generate contaminating debris by friction due to thermal contraction, the debris are prevented from coming into the processing space, so that contamination of the wafer 10 can be prevented.

As shown FIG. 2, a temperature control unit, e.g., a coolant path 34 is installed in the buffer plate 32. A coolant supplied from a coolant supply line 35, for example, cooling water, Galden (a registered trademark of the Ausimont Company) etc. flows through the coolant path 34 to cool the buffer plate 32 and then is discharged from a coolant discharge line 36. The coolant discharged from the coolant discharge line 36 is cooled by a cooler unit 37 to be recirculated to the coolant path 34 through the coolant supply line 35. The cooler unit 37 regulates the coolant flow rate and/or the coolant temperature according to a signal from controller 6. While the coolant supply line 35 and the coolant discharge line 36 are depicted simply in FIG. 2, they are constituted, for example, by lines penetrating the bottom wall of the processing vessel 2. Further, the temperature control unit of the buffer plate 32 can have, in addition to the coolant path, e.g., a heating unit such as a resistance heating element or the like. In this case, the temperature of the buffer plate 32 can be controlled over a broader temperature range. It is preferable for the temperature of the buffer plate 32 to be higher than the temperature depending on the film forming process type e.g., the temperature at which a thin film or a by-product can deposit thereon. Accordingly, they are prevented from depositing on the buffer plate 32.

Further, as shown FIG. 1, a supporting member 24 for transferring the wafer 10 supports the peripheral portion of the wafer 10 and is raised by an elevator unit 25. The supporting member 24, except during transfer, sits on an end portion 26 which is formed in the mounting table 3. A wafer transfer port 27 is formed in the sidewall of the processing vessel 2. The wafer transfer port 27 communicates with a preliminary vacuum chamber (not shown) by a gate valve 28. In the upper portion of the processing vessel 2, the gas supply unit 29 composed of a gas shower head is formed to face the mounting table 3, and film forming gases supplied from respective multiple gas supply lines (in FIG. 1, only gas supply lines 29a and 29b are indicated for simplicity) are individually introduced into the processing vessel 2.

Next, the operation of the embodiment described above will be discussed. First, the mounting table 3 is heated to a temperature approximately within the range from e.g., 400° C. to 700° C. by the heaters 71 and 72. Meanwhile, the inside of the processing vessel 2 is evacuated by the vacuum pump 20. Through the transfer port 27, the wafer 10, i.e., a substrate is introduced into the processing vessel 2 by an arm (not shown) to be mounted on the mounting table 3 by the supporting member 24. After the wafer 10 is heated to a predetermined processing temperature approximately within a range from 400° C. to 700° C. and while the processing atmosphere is maintained at a predetermined pressure, for example, approximately within a range from 100 Pa to 1000 Pa, processing gases, e.g., TiCl₄ (titanium tetrachloride) and NH₃ (ammonia) of the predetermined flow rates are individually introduced into the processing vessel 2 from the gas supply unit 29. The processing gases then react thermochemically to form a thin film, for example, TiN on the surface of the wafer 10. At this time, the surface temperature of the buffer plate 32 is set at a temperature, e.g., 170° C., whereby forming of a TiN film or by-product would not occur. Further, H₂ (hydrogen) instead of NH₃ can be supplied to form a Ti film.

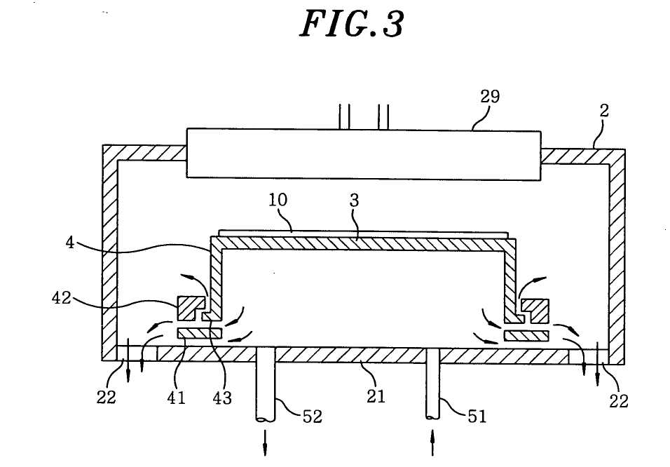

Then, in the space S of the mounting table 3's underside, the purge gas, e.g., N₂ gas is supplied from the purge gas supply line 51. The pressure in the space S is set at a pressure, e.g., 1330 Pa, which is higher than that of the processing atmosphere by the pressure control unit 55. Therefore, as shown in FIG. 3, the purge gas of the space S leaks out into the processing atmosphere through the minute gap between the bottom wall 21 of the processing vessel 2 and the heat insulating material 41, between the heat insulating material 41 and the pressing member 42, and between the lower end of the cylindrical part 4 and the heat insulating material 41 or the pressing member 42. Accordingly, the processing gas from the processing atmosphere side is prevented from leaking into the space S.

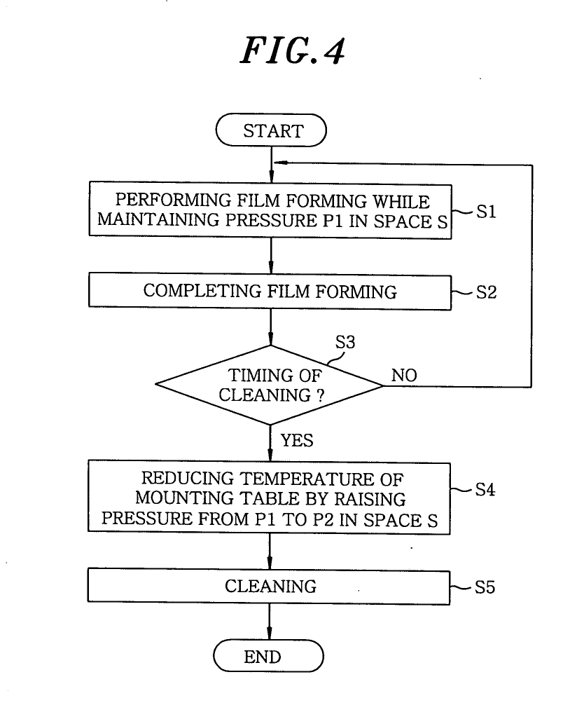

After completing one film forming process, the same process is performed for a next wafer 10. When the total film thickness reaches a predetermined film thickness after repeating such film forming processes, the inside of the processing vessel 2 is cleaned. FIG. 4 is a flow chart which describes this process. In step Si, the film forming process as mentioned above is performed while the pressure in the space S is maintained at a predetermined pressure P1. After the film forming process is completed (step S2), it is determined whether cleaning needs to be performed (step S3). If cleaning need not be performed, the film forming process is performed for a next wafer. If it is time to clean, supplying electric power to the heaters 71 and 72 of the mounting table 3 are stopped and the temperature of the mounting table 3 is reduced to a temperature, for example, 250□, for the cleaning process. Here, the pressure in the space S is raised from the pressure P1 for film forming to the pressure P2, e.g., 2660 Pa so as to speed up the temperature reduction from increasing thermal dissipation by the mounting table 3 (step S4). If the temperature of the mounting table 3 is reduced to the set temperature, a cleaning gas, e.g., ClF₃ (chlorine trifluoride) or F₂-gas (fluorine) with HF-gas (hydrogen fluoride) is supplied into the inside of the processing vessel 2 to perform the cleaning process by etching which would remove thin films deposited on the inner wall of the processing vessel 2 or the mounting table 3 (step S5).

While performing the cleaning process, the pressure in the space S is maintained at the pressure P2, but it can be lower than the pressure P2 to lower thermal dissipation. Here also, to prevent leakage of the cleaning gas into the space S, the pressure in the space S is set higher than the pressure of the processing atmosphere.

Further, as a control method for setting the pressure in the space S higher than that of the processing atmosphere, it is possible to control the pressure in the space S by inputting a signal from a pressure sensor installed in the processing vessel 2 (not shown) to the controller 6, and based on the detected signal from the pressure sensor and the pressure detection unit 57, for example, control the pressure in the space S to be a certain level higher than the pressure in the processing vessel 2 or to be at a level which is a certain multiple of the pressure in the processing vessel 2.

According to the embodiment discussed above, while the cylindrical part 4 (enclosing unit) vertically extending down from the mounting table 3 along its periphery is integrated in the underside of the mounting table 3, on which a wafer 10 is mounted, the flange 43 in the lower end of the cylindrical part 4 is fitted inbetween the heat insulating material 41 and the pressing member 42. Surface contacts are formed between the bottom wall of the processing vessel 2 and the heat insulating material 41, between the heat insulating material 41 and the pressing member 42, between the lower end of the cylindrical part 4 and the heat insulating material 41 or the pressing member 42. As a result, the space S under the mounting table 3 is airtightly sealed and isolated from the processing atmosphere and, thereby, the pressure in the space S is maintained higher than in the processing atmosphere by the purge gas. Accordingly, it is possible to prevent the gas from leaking into the rear surface of the mounting table 3; namely, the processing gas or the cleaning gas is prevented from leaking into the space S from the processing atmosphere. As a result, the thermocouples 75 and 76 and the power line members 73 and 74 can be protected from corrosion. Further, since pressure in the space S is maintained at a level which would satisfy a predetermined degree of temperature detection accuracy by enhancing the thermal conductivity of the minute gap formed in the contact regions between thermocouples 75 and 76 and the mounting table 3, stable temperature control of the mounting table is possible.

Further, since an O-Ring is not used so as to form an airtight sealing between the space S and the processing atmosphere, thermal degradation of the O-Ring is not an issue. Therefore, the distance between the mounting table 3 and the bottom of the processing vessel 2 can be reduced, thereby making the overall volume of the processing vessel 2 smaller. In addition, because the space S which takes up the entire region of the mounting table 3's underside is isolated from the processing atmosphere, there is no limitation on the installed numbers and the installation positions of thermocouples 75 and 76 and power line members 73 and 74. Thus, the mounting table 3 can be divided into desired sections to control precisely and strictly. As a result, a superior uniformity of the surface temperature of the wafer 10 can be obtained. In addition, since the respective diameters of the thermocouples 75 and 76 and the power line members 73 and 74 are small, the amount of heat transmitted through each of them is minimal. Therefore, by interposing an O-Ring between each of them and the bottom of the processing vessel 2, a tight sealing can be achieved.

Further, in case of reducing the temperature of the mounting table 3 so as to perform the next process after completing the film forming process (for example, for cleaning), the pressure in the space S is raised to speed up the thermal dissipation of the mounting table 3. In this way, the temperature of the mounting table 3 can be reduced to a predetermined temperature rapidly. Thus, the cleaning process can be performed rapidly, and operating efficiency of the apparatus is improved. In contrast, if the pressure in the processing atmosphere is raised so as to reduce the temperature of the mounting table 3 rapidly, it would take a long time to reduce the processing atmosphere to a set pressure in the next cleaning process. Therefore, raising the pressure in the space S is highly efficient.

Further, heat is transferred by the processing gas from the mounting table 3 to the buffer plate 32 disposed along the periphery of the mounting table 3. Therefore, when the temperature of the buffer plate 32 processing the first wafer 10 is compared, the temperature of the buffer plate 32 processing the next multiple wafers 10 is higher. Therefore, for wafers 10 (between successive surfaces), the gas consumption levels on the surface of the wafer 10 become different, so the gas concentration distribution can be changed. However, because the buffer plate 32 is cooled by the temperature control unit to suppress the temperature variation of the buffer plate 32 processing each wafer 10, a superior surface uniformity for each film forming process, e.g., film thickness, can be attained.

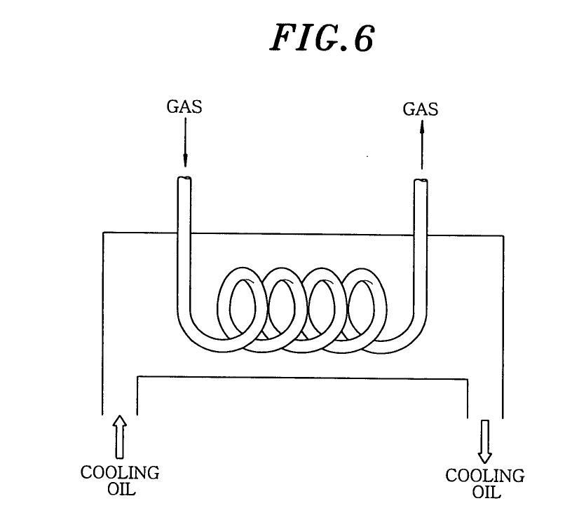

In the embodiment discussed above, when reducing the temperature of the mounting table 3, the pressure in the space S is raised to speed up thermal dissipation. However, by installing a purge gas cooler unit in the purge gas supply line 51 to cool purge gas, the temperature reduction of the mounting table 3 can also be promoted. FIG. 6 shows a simplified example of a purge gas cooler unit. Otherwise, raising pressure in the space S can be combined with cooling of the purge gas. Further, as for the case of reducing the temperature of the mounting table 3, it is not limited to the cleaning process, and it can also be applied to when shifting one process to a different process, for example, forming different films successively when the latter film forming process's temperature is lower than the former film forming process.

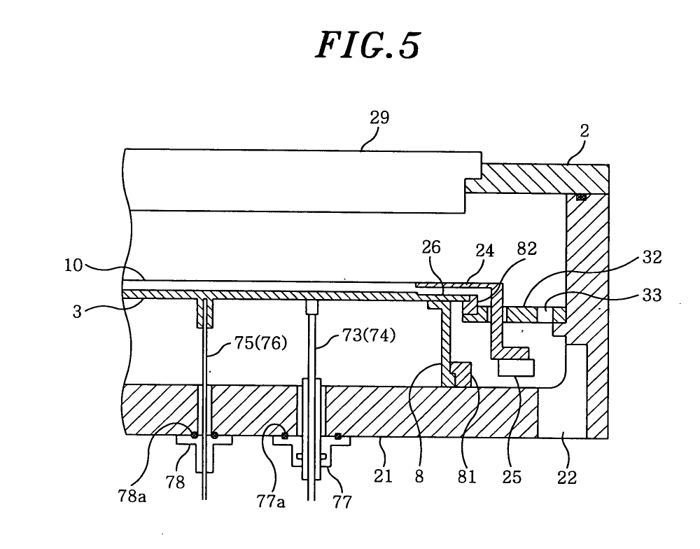

The configuration which isolates the space S in the underside of the mounting table 3 from the processing atmosphere is not limited to the configuration of FIG. 1. For example, as shown FIG. 5, a cylindrically shaped heat insulating member 8 can be installed to compose an enclosing unit by surrounding the space S under the mounting table 3. Then by bending the upper portion of the insulating member 8, the top surface of the bent portion can be in surface contact with the bottom surface of the mounting table 3, while by bending the lower end of the heat insulating material 8, the bottom surface of the bent portion can be in surface contact with the bottom wall 21 of the processing vessel 2. In this way, heat insulating efficiency between the mounting table 3 and the bottom wall 21 can be enhanced.

Further, the lower end of the heat insulating material 8 is pressurized by a ring-shaped pressing member 81. Between the pressing member 81 and the heat insulating material 8, between the pressing member 81 and the bottom wall 21, surface contacts are formed. Further, the gap between the peripheral portion of the mounting table 3 and the buffer plate 32 is occupied by a ring-shaped intermediate member 82. The intermediated member 82, the mounting table 3 and the buffer plate 32 are in surface contact with one another, so that contaminating debris or metal particles are prevented from being scattered into the processing atmosphere.

As discussed above, the present invention can not only be applied to forming a W film using WF₆ gas (tungsten hexafluoride) and H₂ gas or SiH₄ (monosilane) gas, it can also be applied to forming a WSi₂ film using WF₆ gas and SiH₂Cl₂ (dichlorosilane) gas. Further, a unit for heating the wafer 10 can be e.g., a heating lamp installed above the mounting table 3 to face the top portion thereof. Alternatively, the present invention can be applied to an apparatus for vacuum processing such as etching or ashing.

What is claimed is:

1. A vacuum processing apparatus comprising:
a processing vessel with a bottom, the vessel drawing a vacuum;
a mounting table installed in the processing vessel for mounting a substrate thereon;
a heating unit for heating the substrate on the mounting table;
a processing gas supply unit for supplying a processing gas into the processing vessel;
an enclosing unit surrounding a space between the mounting table and the bottom of the processing vessel so that the space is isolated from a processing space of the processing vessel;
a purge gas supply unit for supplying a purge gas into the space surrounded by the enclosing unit;
a purge gas exhaust unit for exhausting the purge gas from the space surrounded by the enclosing unit;
a control unit for controlling the purge gas supply unit and/or the purge gas exhaust unit to regulate the pressure in the space surrounded by the enclosing unit; and
a temperature detecting unit which penetrates the bottom of the processing vessel and runs through the space surrounded by the enclosing unit with a top end of the temperature detecting unit contacting the mounting table,
wherein the enclosing unit has a lower end in surface contact with the bottom of the processing vessel and the control unit regulates the pressure in the space surrounded by the enclosing unit to be higher than that in the processing space of the processing vessel.

2. The vacuum processing apparatus as claimed in claim 1, wherein the heating unit has a resistance heating element disposed in the mounting table, and a power line member for supplying electric power to the heating unit penetrates the bottom of the processing vessel and runs through the space surrounded by the enclosing unit.

3. The vacuum processing apparatus as claimed in claim 1, wherein the control unit raises the pressure in the space surrounded by the enclosing unit.

4. The vacuum processing apparatus as claimed in claim 1, further comprising a purge gas cooler unit for cooling the purge gas.

5. The vacuum processing apparatus as claimed in claim 4, wherein the control unit also controls the purge gas cooler unit.

6. The vacuum processing apparatus as claimed in claim 1, wherein the processing vessel has a sidewall portion while a buffer plate is provided between the sidewall portion and the enclosing unit to divide the processing space of the processing vessel into a processing space side and an exhausting space side, the buffer plate having a plurality of holes for permitting the processing space side to communicate with the exhausting space side, and a processing gas exhaust port being provided in the sidewall portion for exhausting the processing gas from the exhausting space side.

7. The vacuum processing apparatus as claimed in claim 6, wherein the buffer plate has a temperature control unit.

8. A vacuum processing method using a vacuum processing apparatus comprising a processing vessel with a bottom, the vessel drawing a vacuum; a mounting table installed in the processing vessel for mounting a substrate thereon; a heating unit for heating the substrate on the mounting table; a processing gas supply unit for supplying a processing gas into the processing vessel; an enclosing unit surrounding a space between the mounting table and the bottom of the processing vessel so that the space is isolated from a processing space of the processing vessel; a purge gas supply unit for supplying a purge gas into the space surrounded by the enclosing unit; a purge gas cooler unit for cooling the purge gas; a purge gas exhaust unit for exhausting the purge gas from the space surrounded by the enclosing unit; a control unit for controlling the purge gas supply unit and/or the purge gas exhaust unit to regulate the pressure in the space surrounded by the enclosing unit; and a temperature detecting unit which penetrates the bottom of the processing vessel and runs through the space surrounded by the enclosing unit, with a top end of the temperature detecting unit contacting the mounting table, wherein the enclosing unit has a lower end in surface contact with the bottom of the processing vessel, the vacuum processing method comprising:
a processing process for vacuum processing of the substrate while regulating the pressure in the space surrounded by the enclosing unit to be higher than that in the processing space of the processing vessel; and
a cooling process for reducing the temperature of the mounting table while maintaining a raised pressure level in the space surrounded by the enclosing unit, both being carried out after the vacuum processing.

9. The vacuum processing method as claimed in claim 8, further comprising a cleaning process for cleaning the inside of the processing vessel after the cooling process.

10. A vacuum processing method using a vacuum processing apparatus comprising a processing vessel with a bottom, the vessel being drawing a vacuum; a mounting table installed in the processing vessel for mounting a substrate thereon; a heating unit for heating the substrate on the mounting table; a processing gas supply unit for supplying a processing gas into the processing vessel; an enclosing unit surrounding a space between the mounting table and the bottom of the processing vessel so that the space is isolated from a processing space of the processing vessel; a purge gas supply unit for supplying a purge gas into the space surrounded by the enclosing unit; a purge gas exhaust unit for exhausting the purge gas from the space surrounded by the enclosing unit; a control unit for controlling the purge gas supply unit and/or the purge gas exhaust unit to regulate the pressure in the space surrounded by the enclosing unit; and a temperature detecting unit which penetrates the bottom of the processing vessel and runs through the space surrounded by the enclosing unit, with a top end of the temperature detecting unit contacting the mounting table, wherein the enclosing unit has a lower end in surface contact with the bottom of the processing vessel, the vacuum processing method comprising:
a processing process for vacuum processing of the substrate while regulating the pressure in the space surrounded by the enclosing unit to be higher than that in the processing space of the processing vessel; and
a cooling process for reducing the temperature of the mounting table while cooling the purge gas by the purge gas cooler unit, both being carried out after the vacuum processing.
